(19) United States
(12) Patent Application Publication
(10) Pub. No.: US 2025/0120288 A1
(43) Pub. Date: Apr. 10, 2025

(54) DISPLAY APPARATUS AND METHOD OF MANUFACTURING THE SAME

(71) Applicant: Samsung Display Co., Ltd., Yongin-si (KR)

(72) Inventors: Hoyun Byun, Yongin-si (KR); Seongsik Choi, Yongin-si (KR)

(21) Appl. No.: 18/750,878

(22) Filed: Jun. 21, 2024

(30) Foreign Application Priority Data
Oct. 4, 2023 (KR) 10-2023-0131928

(51) Int. Cl. H10K 59/80; H10K 59/12

(52) U.S. Cl. CPC H10K 59/873; H10K 59/1201

(57) ABSTRACT

A display apparatus and a method of manufacturing the same are provided. The display apparatus includes a display panel, a cover window covering one surface of the display panel, and a first adhesive member between the display panel and the cover window, wherein a surface inclination angle of the first adhesive member is at least about 15 degrees and at most about 40 degrees.

### CROSS-REFERENCE TO RELATED APPLICATION

This application claims priority to and the benefit of Korean Patent Application No. 10-2023-0131928, filed on Oct. 4, 2023, in the Korean Intellectual Property Office, the entire disclosure of which is hereby incorporated by reference.

### BACKGROUND

### 1. Field

One or more embodiments of the present disclosure relate to a display apparatus and a method of manufacturing the same, and for example, to a display apparatus in which the area of a dead space is reduced and a method of manufacturing the display apparatus.

### 2. Description of the Related Art

Recently, display apparatuses have been utilized in a large variety of ways. In addition, display apparatuses have become thinner and lighter, and thus, their range of use has widened. As the use of display apparatuses has diversified, one or more suitable methods have been studied to design the form of display apparatuses.

In display apparatuses, a cover window for protecting lower structures is positioned on a display panel, and an optically clear adhesive is utilized to attach the cover window to the display panel. The optically clear adhesive is desired or required to have excellent or suitable moisture resistance, heat resistance, and/or adhesion along with basic or suitable optical properties.

The optically clear adhesive may be applied in a liquid state and hardened and accordingly may form (or provide) an inclined portion on the periphery of the display panel. Due to the inclined portion, a peripheral area of the display panel may require a larger area.

The above information disclosed in this Background section is only for enhancement of understanding of the background of the disclosure and therefore it may contain information that does not constitute prior art.

### SUMMARY

Aspects of one or more embodiments of the present disclosure include a display apparatus in which an adhesive member having an improved inclination angle is included to reduce the area of a dead space and a method of manufacturing the display apparatus.

Additional aspects will be set forth in part in the description which follows and, in part, will be apparent from the description, or may be learned by practice of the presented embodiments of the disclosure.

According to one or more embodiments of the present disclosure, a display apparatus includes a display panel, a cover window covering one surface of the display panel, and a first adhesive member between the display panel and the cover window, wherein a surface inclination angle of the first adhesive member is at least about 15 degrees and at most (e.g., less than) about 40 degrees.

In one or more embodiments, the first adhesive member may include a hydrophobic material.

In one or more embodiments, the first adhesive member may include at least one of butyl acrylate or perfluoroethyl acrylate.

In one or more embodiments, a content (e.g., amount) of the butyl acrylate may be about 20 wt % to about 65 wt %.

In one or more embodiments, a content (e.g., amount) of the perfluoroethyl acrylate may be about 5 wt % to about 35 wt %.

In one or more embodiments, the first adhesive member may be in a display area and a peripheral area of the display panel, and the peripheral area may be around (e.g., surround) the display area.

In one or more embodiments, the first adhesive member may include an inclined portion inclined with respect to the display panel in the peripheral area, and a width of the inclined portion of the first adhesive member may be about 1.19 times to about 3.73 times greater than a thickness of the first adhesive member.

In one or more embodiments, the display apparatus may further include a second adhesive member on a periphery of the first adhesive member.

In one or more embodiments, the second adhesive member may include the same material as a material of the first adhesive member.

In one or more embodiments, the second adhesive member may include a different material from the first adhesive member.

In one or more embodiments, a surface inclination angle of the second adhesive member may be greater than the surface inclination angle of the first adhesive member.

In one or more embodiments, the first adhesive member and the second adhesive member may each include at least one of butyl acrylate or perfluoroethyl acrylate, wherein a content (e.g., amount) of the butyl acrylate in the second adhesive member may be less than a content (e.g., amount) of the butyl acrylate in the first adhesive member.

In one or more embodiments, the first adhesive member and the second adhesive member may each include at least one of butyl acrylate or perfluoroethyl acrylate, wherein a content (e.g., amount) of the perfluoroethyl acrylate in the second adhesive member may be greater than a content (e.g., amount) of the perfluoro ethylacrylate in the first adhesive member.

In one or more embodiments, the display apparatus may further include a hydrophobic coating layer between the first adhesive member and the second adhesive member.

According to one or more embodiments of the present disclosure, a method of manufacturing a display apparatus includes preparing a display panel, arranging a first adhesive member in a display area and a peripheral area of the display panel, and attaching, by arranging a cover window on the first adhesive member, the cover window to the display panel, wherein a surface inclination angle of the first adhesive member is at least about 15 degrees and at most about 40 degrees.

In one or more embodiments, the first adhesive member may include at least one of butyl acrylate or perfluoroethyl acrylate.

In one or more embodiments, a content (e.g., amount) of the butyl acrylate may be about 20 wt % to about 65 wt %.

In one or more embodiments, a content (e.g., amount) of the perfluoroethyl acrylate may be about 5 wt % to about 35 wt %.

In one or more embodiments, the method may further include coating a periphery of the first adhesive member with a hydrophobic material.

In one or more embodiments, the method may further coating the hydrophobic material between the first adhesive member and a second adhesive member.

### BRIEF DESCRIPTION OF THE DRAWINGS

The above and other aspects, features, and/or principles of certain embodiments of the disclosure will be more apparent from the following description taken in conjunction with the accompanying drawings, in which:

FIG. 1 is a schematic plan view of a display apparatus according to one or more embodiments of the present disclosure;

FIG. 2 is a schematic plan view of a display panel that may be included in the display apparatus of FIG. 1, according to one or more embodiments of the present disclosure;

FIG. 3 is an equivalent circuit diagram of a pixel circuit configured to drive a pixel, according to one or more embodiments;

FIG. 4 is a schematic cross-sectional view of a display panel taken along the line IV-IV′ of FIG. 1, according to one or more embodiments of the present disclosure;

FIG. 5 is a schematic cross-sectional view of a display apparatus taken along the line V-V′ of FIG. 2, according to one or more embodiments of the present disclosure;

FIG. 6 is a table for comparing detailed components of a first adhesive member according to Embodiments 1 to 3 and a comparative example;

FIGS. 7 and 8 are each a schematic cross-sectional view of a display apparatus taken along the line V-V′ of FIG. 2, according to embodiments of the present disclosure, and are similar to FIG. 5; and

FIGS. 9-14 are schematic diagrams of a method of manufacturing a display apparatus, according to one or more embodiments of the present disclosure.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Reference will now be made in more detail to one or more embodiments, examples of which are illustrated in the accompanying drawings, wherein like reference numerals refer to like elements throughout, and duplicative descriptions thereof may not be provided. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

As used herein, the term “and/or” includes any and all combinations of one or more of the associated listed items. Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from a, b, and c,” “at least one from among a, b, and c,” “one from among a, b, and c”, “at least one of a to c” indicates only a, only b, only c, both a and b, both a and c, both b and c, all of a, b, and c, or variations thereof.

As the present description allows for one or more suitable changes and numerous embodiments, certain embodiments will be illustrated in the drawings and described in the written description. Aspects and features of one or more embodiments and methods of accomplishing the same will become apparent from the following detailed description of the one or more embodiments, taken in conjunction with the accompanying drawings. However, the present embodiments may have different forms and should not be construed as being limited to the descriptions set forth herein.

One or more embodiments will be described in more detail with reference to the accompanying drawings. Those elements that may each independently be the same or are in correspondence with each other are rendered the same reference numeral regardless of the drawing number, and redundant descriptions thereof are omitted.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

The singular forms “a,” “an,” and “the” as used herein are intended to include the plural forms as well, unless the context clearly indicates otherwise.

It will be further understood that the terms “comprises,” “comprising,” “includes,” “including,” “have,” and “having,” when used in this specification, specify the presence of the stated features, integers, steps, operations, elements, and/or components, but do not preclude the presence or addition of one or more other features, integers, steps, operations, elements, components, and/or groups thereof.

It will be understood that when an element, such as a layer, film, region or substrate, is referred to as being “on” or “connected to” another element, it can be directly on or connected to the other element, or one or more intervening elements may be present. For example, if (e.g., when) layers, regions, or elements are referred to as being electrically connected to each other, they may be directly electrically connected to each other and/or may be indirectly electrically connected to each other with intervening layers, regions, or elements therebetween. In addition, it will also be understood that when an element is referred to as being “between” two elements, it can be the only element between the two elements, or one or more intervening elements may also be present.

Spatially relative terms, such as “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Sizes of elements in the drawings may be exaggerated or reduced for convenience of explanation. For example, because sizes and thicknesses of elements in the drawings are illustrated (e.g., arbitrarily illustrated) for convenience of explanation, the present disclosure is not limited thereto.

When an embodiment may be implemented differently, a certain process order may be performed differently from the described order. For example, two consecutively described processes may be performed substantially at the same time or performed in an order opposite to the described order.

As used herein, the expression “A and/or B” refers to A, B, or A and B.

The x-axis, the y-axis, and the z-axis are not limited to three axes of the rectangular coordinate system and may be interpreted in a broader sense. For example, the x-axis, the y-axis, and the z-axis may be normal (e.g., perpendicular) to one another or may represent different directions that are not normal (e.g., perpendicular) to one another.

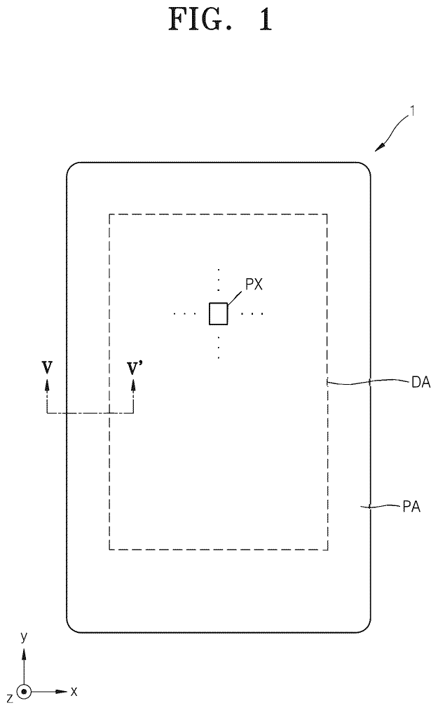

FIG. 1 is a schematic plan view of a display apparatus 1 according to one or more embodiments of the present disclosure.

Referring to FIG. 1, the display apparatus 1 may include a display area DA and a peripheral area PA outside the display area DA. A plurality of pixels PX may be arranged in the display area DA, and the display area DA may provide a certain image through light emitted from the plurality of pixels PX. A pixel PX may be defined as an emission area where a light-emitting element driven by a pixel circuit emits light. Each pixel PX may be to emit, for example, red, green, or blue light. In one or more embodiments, each pixel PX may be to emit red, green, blue, or white light. An image may be provided by light emitted from each of a plurality of light-emitting elements through the pixel PX.

The peripheral area PA may be an area where an image is not provided. The peripheral area PA may be outside the display area DA and may be entirely or partially around (e.g., surround) the display area DA. A driver for providing an electrical signal or power to the display area DA may be arranged in the peripheral area PA. A pad portion, which is an area to which an electronic element or a printed circuit board may be electrically connected, may be arranged in the peripheral area PA.

Hereinafter, it is assumed that the display apparatus 1 includes an organic light-emitting diode (OLED) as a light-emitting element, but the display apparatus 1 according to the present disclosure is not limited thereto. In one or more embodiments, the display apparatus 1 may be a light-emitting display including an inorganic light-emitting diode, that is, an inorganic light-emitting display. The inorganic light-emitting diode may include a PN junction diode including inorganic semiconductor-based materials. When a voltage is applied to the PN junction diode in a forward direction, holes and electrons are injected, and light of a certain color may be emitted by converting energy generated by recombination of the holes and electrons into light energy. The inorganic light-emitting diode described above may have a width of several to hundreds of micrometers, and in one or more embodiments, the inorganic light-emitting diode may be referred to as a micro LED. In one or more embodiments, the display apparatus 1 may be a quantum dot light-emitting display.

The display apparatus 1 may have a quadrilateral shape in a plan view, as shown in FIG. 1, but the present disclosure is not limited thereto. The display apparatus 1 may have one or more suitable shapes, for example, a polygonal shape such as a triangular shape, a circular shape, an oval shape, or an atypical shape, in a plan view. As an example, the display apparatus 1 may have a quadrilateral shape having a short side in a first direction (e.g., a direction x or a direction −x) and a long side in a second direction (e.g., a direction y or a direction −y), as shown, for example, in FIG. 1. As another example, the display apparatus 1 may have a side in a first direction and a side in a second direction having the same length. As another example, the display apparatus 1 may have a long side in a first direction and a short side in a second direction. In one or more embodiments, the display apparatus 1 may have round corners.

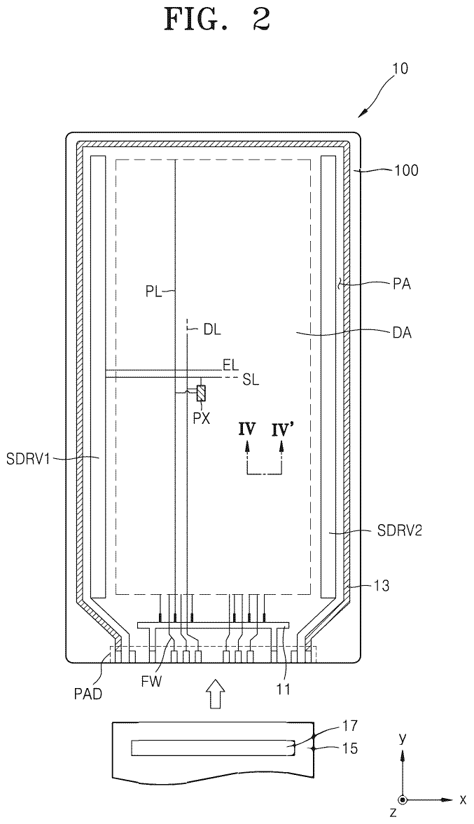

FIG. 2 is a schematic plan view of a display panel 10 that may be included in the display apparatus 1 of FIG. 1, according to one or more embodiments of the present disclosure.

Referring to FIG. 2, one or more suitable elements constituting the display panel 10 may be arranged on a substrate 100. Pixels PX may be arranged in the display area DA. The display area DA may be covered by an encapsulation member and protected from external air or moisture.

Pixel circuits configured to drive the pixels PX may each be electrically connected to outer circuits arranged in the peripheral area PA. A first scan driving circuit SDRV1, a second scan driving circuit SDRV2, a terminal portion PAD, a driving voltage supply line 11, and a common voltage supply line 13 may be arranged in the peripheral area PA.

The first scan driving circuit SDRV1 may be configured to apply a scan signal to each of the pixel circuits configured to drive the pixels PX through a scan line SL. The first scan driving circuit SDRV1 may be configured to apply an emission control signal to each pixel circuit through an emission control line EL. The second scan driving circuit SDRV2 may be opposite to the first scan driving circuit SDRV1 with respect to the display area DA and may be substantially parallel to the first scan driving circuit SDRV1. Some of the pixel circuits of the pixels PX of the display area DA may be electrically connected to the first scan driving circuit SDRV1, and the others may be electrically connected to the second scan driving circuit SDRV2.

The terminal portion PAD may be arranged at one side of the substrate 100. The terminal portion PAD may not be covered by an insulating layer but may be exposed and connected to a display circuit board 15. A display driver 17 may be arranged on the display circuit board 15.

The display driver 17 may generate a control signal which is transmitted to the first scan driving circuit SDRV1 and the second scan driving circuit SDRV2. The display driver 17 may generate a data signal, and the generated data signal may be transmitted to the pixel circuits of the pixels PX through a fan-out wire FW and a data line DL connected to the fan-out wire FW.

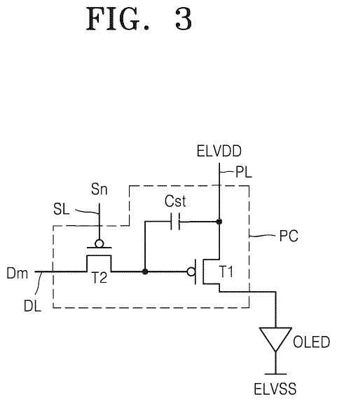

The display driver 17 may supply a driving voltage ELVDD (see, e.g., FIG. 3) to the driving voltage supply line 11 and may supply a common voltage ELVSS (see, e.g., FIG. 3) to the common voltage supply line 13. The driving voltage ELVDD may be applied to the pixel circuits of the pixels PX through a driving voltage line PL connected to the driving voltage supply line 11, and the common voltage ELVSS may be connected to the common voltage supply line 13 and applied to an opposite electrode of a display element of a pixel PX.

The driving voltage supply line 11 may extend in the direction x below the display area DA. The common voltage supply line 13 may have a loop shape of which one side is open and thus may be around (e.g. may partially surround) the display area DA.

FIG. 3 is an equivalent circuit diagram of a pixel circuit PC configured to drive a pixel PX, according to one or more embodiments of the present disclosure.

Referring to FIG. 3, the pixel circuit PC may be connected to an organic light-emitting diode OLED to implement light emission of the pixels PX. The pixel circuit PC includes a driving transistor T1, a switching transistor T2, and a storage capacitor Cst. The switching transistor T2 may be connected to the scan line SL and the data line DL and may be configured to transmit a data signal Dm input through the data line DL to the driving transistor T1 according to a scan signal Sn input through the scan line SL.

The storage capacitor Cst may be connected to the switching transistor T2 and the driving voltage line PL and may store a voltage corresponding to a difference between a voltage received from the switching transistor T2 and the driving voltage ELVDD supplied to the driving voltage line PL.

The driving transistor T1 may be connected to the driving voltage line PL and the storage capacitor Cst, and may be configured to control a driving current flowing in the organic light-emitting diode OLED from the driving voltage line PL to correspond to the voltage stored in the storage capacitor Cst. The organic light-emitting diode OLED may be to emit light having certain brightness according to the driving current.

Although FIG. 3 shows a case in which the pixel circuit PC includes two transistors and one storage capacitor, the present disclosure is not limited thereto.

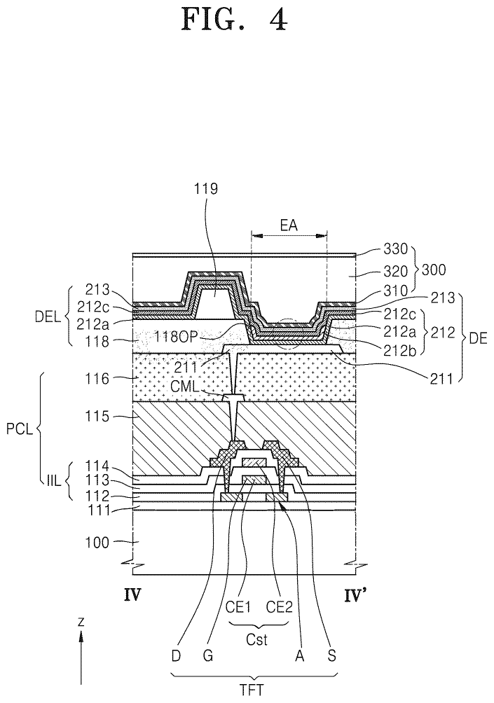

FIG. 4 is a schematic cross-sectional view of the display panel 10 according to one or more embodiments of the present disclosure. More specifically, FIG. 4 corresponds to a cross-sectional view of the display panel 10, taken along the line IV-IV′ of FIG. 2, according to one or more embodiments of the present disclosure, and shows only the display panel 10. Hereinafter, a stacked structure of the display panel 10 will be briefly described with reference to FIG. 4.

Referring to FIG. 4, the display panel 10 may include the substrate 100, a buffer layer 111, a pixel circuit layer PCL, a display element layer DEL, and an encapsulation layer 300.

The substrate 100 may include glass or may include polymer resin, such as polyethersulfone, polyarylate, polyetherimide, polyethylene naphthalate, polyethylene terephthalate, polyphenylene sulfide, polyimide, polycarbonate, cellulose triacetate, and/or cellulose acetate propionate. The substrate 100 including polymer resin may be flexible, rollable and/or bendable. The substrate 100 may have a multi-layer structure including a base layer and a barrier layer, the base layer including the above-described polymer resin.

The buffer layer 111 may include an inorganic insulating material, such as silicon nitride, silicon oxynitride, and/or silicon oxide, and may have a single-layer or multi-layer structure including the above-described inorganic insulating material.

The pixel circuit layer PCL may be arranged on the buffer layer 111. The pixel circuit layer PCL may include a transistor TFT included in a pixel circuit, and an inorganic insulating layer IIL, a first planarization layer 115, and a second planarization layer 116 arranged under and/or over elements of the transistor TFT. The inorganic insulating layer IIL may include a first gate insulating layer 112, a second gate insulating layer 113, and an interlayer insulating layer 114.

The transistor TFT may include a semiconductor layer A, and the semiconductor layer A may include polysilicon. In one or more embodiments, the semiconductor layer A may include amorphous silicon, an oxide semiconductor, and/or an organic semiconductor. The semiconductor layer A may include a channel region, and a drain region and a source region respectively arranged on both sides (e.g., opposite sides) of the channel region. A gate electrode G may overlap the channel region.

The gate electrode G may include a low-resistance metal material. The gate electrode G may include a conductive material including molybdenum (Mo), aluminum (Al), copper (Cu), titanium (Ti), and/or the like, and may have a multi-layer or single-layer structure including the above-described material.

The first gate insulating layer 112 between the semiconductor layer A and the gate electrode G may include an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). Zinc oxide (ZnOₓ) may be zinc oxide (ZnO) and/or zinc peroxide (ZnO₂).

The second gate insulating layer 113 may cover the gate electrode G. Similar to the first gate insulating layer 112, the second gate insulating layer 113 may include an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). Zinc oxide (ZnOₓ) may be zinc oxide (ZnO) and/or zinc peroxide (ZnO₂).

An upper electrode CE2 of the storage capacitor Cst may be arranged on the second gate insulating layer 113. The upper electrode CE2 may overlap the gate electrode G arranged under the upper electrode CE2. In this regard, the gate electrode G and the upper electrode CE2 overlapping each other with the second gate insulating layer 113 therebetween may constitute the storage capacitor Cst of the pixel circuit. For example, the gate electrode G may serve as a lower electrode CE1 of the storage capacitor Cst. As described above, the storage capacitor Cst and the transistor TFT may overlap each other. In one or more embodiments, the storage capacitor Cst may not overlap the transistor TFT.

The upper electrode CE2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W) and/or copper (Cu), and may have a single-layer or multi-layer structure including the above-described material.

The interlayer insulating layer 114 may cover the upper electrode CE2. The interlayer insulating layer 114 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and/or zinc oxide (ZnOₓ). Zinc oxide (ZnOₓ) may be zinc oxide (ZnO) and/or zinc peroxide (ZnO₂). The interlayer insulating layer 114 may have a single-layer or multi-layer structure including the above-described inorganic insulating material.

A drain electrode D and a source electrode S may each be on the interlayer insulating layer 114. The drain electrode D and the source electrode S may each include a highly conductive material. The drain electrode D and the source electrode S may each include a conductive material including molybdenum (Mo), aluminum (Al), copper (Cu), titanium (Ti), and/or the like, and may have a multi-layer or single-layer structure including the above-described material. In one or more embodiments, the drain electrode D and the source electrode S may each have a multi-layer structure of titanium (Ti)/aluminum (Al)/titanium (Ti).

The first planarization layer 115 may cover the drain electrode D and the source electrode S. The first planarization layer 115 may include an organic insulating layer. The first planarization layer 115 may include an organic insulating material, such as a general commercial polymer, such as polymethylmethacrylate (PMMA) and/or polystyrene (PS), a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, and/or any suitable blend thereof.

A connection electrode CML may be arranged on the first planarization layer 115. In this regard, the connection electrode CML may be connected to the drain electrode D or the source electrode S through a contact hole in the first planarization layer 115. The connection electrode CML may include a highly conductive material. The connection electrode CML may include a conductive material including molybdenum (Mo), aluminum (Al), copper (Cu), titanium (Ti), and/or the like, and may have a multi-layer or single-layer structure including the above-described material. In one or more embodiments, the connection electrode CML may have a multi-layer structure of titanium (Ti)/aluminum (Al)/titanium (Ti).

The second planarization layer 116 may cover the connection electrode CML. The second planarization layer 116 may include an organic insulating layer. The second planarization layer 116 may include an organic insulating material, such as a general commercial polymer, such as polymethylmethacrylate (PMMA) and/or polystyrene (PS), a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, and/or any suitable blend thereof.

The display element layer DEL may be arranged on the pixel circuit layer PCL. The display element layer DEL may include a display element DE. The display element DE may be the organic light-emitting diode OLED. A pixel electrode 211 of the display element DE may be electrically connected to the connection electrode CML through a contact hole in the second planarization layer 116.

The pixel electrode 211 may include conductive oxide, such as indium tin oxide (ITO), indium zinc oxide (IZO), zinc oxide (ZnO), indium oxide (In₂O₃), indium gallium oxide (IGO), and/or aluminum zinc oxide (AZO). In one or more embodiments, the pixel electrode 211 may include a reflection layer including silver (Ag), magnesium (Mg), aluminum (Al), platinum (Pt), palladium (Pd), gold (Au), nickel (Ni), neodymium (Nd), iridium (Ir), chromium (Cr), and/or any suitable compound thereof. In one or more embodiments, the pixel electrode 211 may further include a layer including ITO, IZO, ZnO, or In₂O₃ on/under the above-described reflection layer.

A pixel-defining layer 118 including an opening 118OP exposing a central portion of the pixel electrode 211 may be arranged on the pixel electrode 211. The pixel-defining layer 118 may include an organic insulating material and/or an inorganic insulating material. The opening 118OP may define an emission area of light emitted from the display element DE (hereinafter referred to as an emission area EA). For example, a width of the opening 118OP may correspond to a width of the emission area EA of the display element DE.

A spacer 119 may be arranged on the pixel-defining layer 118. The spacer 119 may be utilized to prevent or reduce destruction of the substrate 100 in a method of manufacturing a display apparatus. A mask sheet may be utilized to manufacture a display panel. In this regard, a defect may be prevented or reduced in which the mask sheet enters the opening 118OP of the pixel-defining layer 118 or comes into close contact with the pixel-defining layer 118 and thus a portion of the substrate 100 is damaged or destroyed by the mask sheet if (e.g., when) a deposition material is deposited on the substrate 100.

The spacer 119 may include an organic insulating material, such as polyimide. In one or more embodiments, the spacer 119 may include an inorganic insulating material, such as silicon nitride or silicon oxide, or may include an organic insulating material and an inorganic insulating material.

In one or more embodiments, the spacer 119 may include a different material than the pixel-defining layer 118. In one or more embodiments, the spacer 119 may include the same material as the pixel-defining layer 118, and in this case, the pixel-defining layer 118 and the spacer 119 may be formed together in a mask process utilizing a halftone mask, and/or the like.

An intermediate layer 212 may be arranged on the pixel-defining layer 118. The intermediate layer 212 may include an emission layer 212b arranged in the opening 118OP of the pixel-defining layer 118. The emission layer 212b may include a high-molecular weight or low-molecular weight organic material emitting light of a certain color.

A first functional layer 212a and a second functional layer 212c may be arranged under and on the emission layer 212b, respectively. The first functional layer 212a may include, for example, a hole transport layer (HTL), or an HTL and a hole injection layer (HIL). The second functional layer 212c is an element arranged on the emission layer 212b and may be optional. The second functional layer 212c may include an electron transport layer (ETL) and/or an electron injection layer (EIL). The first functional layer 212a and/or the second functional layer 212c may be common layers that entirely cover the substrate 100 as an opposite electrode 213 described in more detail below does.

The opposite electrode 213 may include a conductive material having a relatively low work function. For example, the opposite electrode 213 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), and/or an alloy thereof. In one or more embodiments, the opposite electrode 213 may further include a layer, such as ITO, IZO, ZnO, or In₂O₃, on a (semi)transparent layer including the above-described material(s).

In one or more embodiments, a capping layer may be further arranged on the opposite electrode 213. The capping layer may include lithium fluoride (LiF), an inorganic material, and/or an organic material.

The encapsulation layer 300 may be arranged on the opposite electrode 213. The encapsulation layer 300 may be arranged on the display element layer DEL and may cover the display element layer DEL. The encapsulation layer 300 may include at least one inorganic encapsulation layer and at least one organic encapsulation layer, and as an example, FIG. 4 shows the encapsulation layer 300 including a first inorganic encapsulation layer 310, an organic encapsulation layer 320, and a second inorganic encapsulation layer 330 which are sequentially stacked on one another.

The first inorganic encapsulation layer 310 and the second inorganic encapsulation layer 330 may include one or more inorganic materials of (e.g., selected from among) aluminum oxide, titanium oxide, tantalum oxide, hafnium oxide, zinc oxide, silicon oxide, silicon nitride, and/or silicon oxynitride. The organic encapsulation layer 320 may include a polymer-based material. Examples of the polymer-based material may include acryl-based resin, epoxy-based resin, polyimide, and polyethylene. In one or more embodiments, the organic encapsulation layer 320 may include acrylate. The organic encapsulation layer 320 may be formed by curing a monomer or coating with a polymer. The organic encapsulation layer 320 may be transparent.

In one or more embodiments, a touch electrode layer may be arranged on the encapsulation layer 300, and an optical functional layer may be arranged on the touch electrode layer. The touch electrode layer may obtain coordinates information according to an external input, for example, a touch event. The optical functional layer may decrease reflectance of light (e.g., external light) that is externally incident toward a display apparatus and/or may improve color purity of light emitted from the display apparatus. In one or more embodiments, the optical functional layer may include a phase retarder and/or a polarizer. The phase retarder may be of a film type or kind or a liquid crystal coating type or kind and may include a λ/2 phase retarder and/or a λ/4 phase retarder. The polarizer may also be of a film type or kind or a liquid crystal coating type or kind. The film type or kind may include an elongated synthetic resin film, and the liquid crystal coating type or kind may include liquid crystals arranged in a certain arrangement. The phase retarder and the polarizer may further include a protection film.

In one or more embodiments, the optical functional layer may include a black matrix and color filters. The color filters may be arranged by taking into account the color of light emitted from each of the pixels of the display apparatus. Each of the color filters may include a pigment or dye of a red, green, or blue color. In one or more embodiments, each of the color filters may further include quantum dots in addition to the above-described pigment or dye. In one or more embodiments, some of the color filters may not include (e.g., may exclude) the above-described pigment or dye, and may include scattered particles such as titanium oxide.

In one or more embodiments, the optical functional layer may include a destructive interference structure. The destructive interference structure may include a first reflection layer and a second reflection layer respectively arranged on different layers. First reflected light and second reflected light respectively reflected by the first reflection layer and the second reflection layer may destructively interfere with each other, thus decreasing reflectance of external light.

An adhesive member may be arranged between the touch sensor layer and the optical functional layer. As the adhesive member, any suitable adhesive layer generally available and/or generally utilized in the art may be employed without limitation. The adhesive member may be a pressure-sensitive adhesive (PSA).

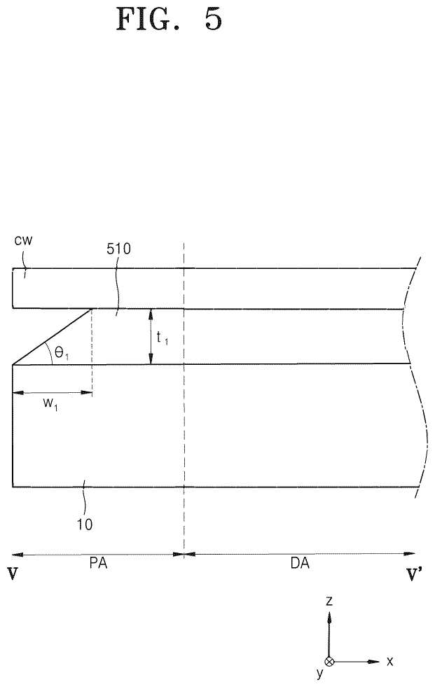

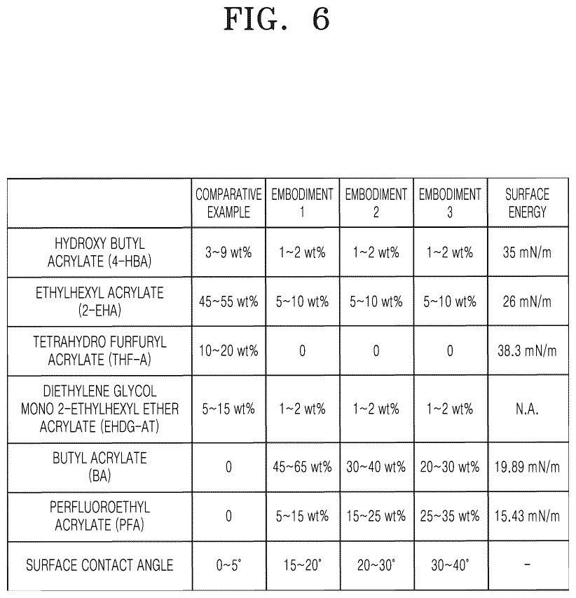

FIG. 5 is a schematic cross-sectional view of the display apparatus 1 according to one or more embodiments of the present disclosure. More specifically, FIG. 5 corresponds to a cross-sectional view of the display apparatus 1, taken along the line V-V′ of FIG. 1, according to one or more embodiments of the present disclosure. FIG. 6 is a table for comparing detailed components of a first adhesive member according to Embodiments 1 to 3 and a comparative example.

Referring to FIG. 5, the display apparatus 1 may include the above-described display panel 10 and a cover window CW covering the display panel 10.

The cover window CW may be arranged on one surface of the display panel 10 to protect the display panel 10. In one or more embodiments, the cover window CW may include sapphire, glass, or plastic. For example, the cover window CW may be ultra-thin glass or colorless polyimide.

The cover window CW may completely cover the display panel 10 to overlap the display area DA and the peripheral area PA of the display panel 10 in a plan view.

An adhesive member 500 may be arranged between the display panel 10 and the cover window CW. In one or more embodiments, the adhesive member 500 may include a first adhesive member 510. The first adhesive member 510 may be an adhesive material capable of attaching the cover window CW to the display panel 10. In one or more embodiments, the first adhesive member 510 may be an optically clear resin (OCR).

The display area DA and the peripheral area PA of the display panel 10 may be coated with the first adhesive member 510. More specifically, the first adhesive member 510 in a liquid state may be spread on the display panel 10 and hardened. In this regard, because of being applied in a liquid state, the first adhesive member 510 may be inclined at a contact angle on the periphery of the display panel 10, for example, in the peripheral area PA. In one or more embodiments, after the first adhesive member 510 is applied to have the contact angle, the first adhesive member 510 may be hardened. Accordingly, the first adhesive member 510 may be inclined at an inclination angle to the display panel 10 after being hardened. For example, a contact angle of the first adhesive member 510 in a liquid state to a lower layer of the first adhesive member 510 may turn into an inclination angle of the first adhesive member 510 as the first adhesive member 510 hardens. For example, the contact angle of the first adhesive member 510 may have substantially the same value as the inclination angle of the first adhesive member 510. In this regard, the contact angle and the inclination angle of the first adhesive member 510 may be defined as an angle to a layer under the first adhesive member 510. For example, the contact angle and the inclination angle of the first adhesive member 510 may refer to an angle of inclination of the first adhesive member 510 to the display panel 10, for example, an optical functional layer or a coating layer that may be arranged on the optical functional layer. In one or more embodiments, the coating layer may include an acrylic polymer material.

Because the first adhesive member 510 has such an inclination angle, a width of the peripheral area PA may be limited. For example, in a case where the first adhesive member 510 is applied in a thickness of 100 μm, if (e.g., when) the inclination angle of the first adhesive member 510 is 45 degrees, a width w1 of an inclined portion of the first adhesive member 510 may be 100 μm. In one or more embodiments, in a case where the first adhesive member 510 is applied in a thickness of 100 μm, if (e.g., when) the inclination angle of the first adhesive member 510 is 10 degrees, the width w1 of the inclined portion of the first adhesive member 510 may be about 568 μm.

For example, as described above, if (e.g., when) the inclination angle of the first adhesive member 510 is large, the width w1 of the inclined portion of the first adhesive member 510 may be small, and accordingly, a width of the peripheral area PA under the first adhesive member 510 may be small. The peripheral area PA is a non-display area, and as a width of the peripheral area PA decreases, dead space may be reduced, and the proportion of an area where an image is displayed in the display apparatus 1 may be maximized or increased.

In one or more embodiments, a surface inclination angle θ1 of the first adhesive member 510 may be at least about 15 degrees but at most about 40 degrees. In this regard, the surface inclination angle θ1 of the first adhesive member 510 may be defined as an inclination angle to a surface of a layer under the first adhesive member 510. For example, the surface inclination angle θ1 of the first adhesive member 510 may refer to an inclination angle of the first adhesive member 510 to the display panel 10, for example, an optical functional layer on the encapsulation layer 300 (e.g., refer to FIG. 4) or a coating layer on the optical functional layer.

Referring to FIG. 6, an adhesive member according to a comparative example may include hydroxy butyl acrylate (4-HBA), ethylhexyl acrylate (2-EHA), tetrahydro furfuryl acrylate (THF-A), and diethylene glycol mono 2-ethylexyl ether acrylate (EHDG-AT).

According to one or more embodiments, the adhesive member according to the comparative example may include at least 3 wt % but less than 9 wt % of hydroxy butyl acrylate (4-HBA), at least 45 wt % but less than 55 wt % of ethylhexyl acrylate (2-EHA), at least 10 wt % but less than 20 wt % of tetrahydro furfuryl acrylate (THF-A), and at least 5 wt % but less than 15 wt % of diethylene glycol mono 2-ethylhexyl ether acrylate (EHDG-AT), based on a total wt % of the adhesive member. It will be understood that, in addition to such monomers, the adhesive member may include an oligomer, a photoinitiator, and/or the like.

A surface inclination angle of the adhesive member according to the comparative example may be at least about 0 degrees but at most about 5 degrees.

According to one or more embodiments, the first adhesive member 510 may include hydroxy butyl acrylate (4-HBA), ethylhexyl acrylate (2-EHA), diethylene glycol mono 2-ethylhexyl ether acrylate (EHDG-AT), butyl acrylate (BA), and perfluoroethyl acrylate (PFA).

In Embodiment 1 of FIG. 6, the first adhesive member 510 may include at least about 1 wt % but at most about 2 wt % of hydroxy butyl acrylate (4-HBA), at least about 5 wt % but at most about 10 wt % of ethyl hexyl acrylate (2-EHA), at least about 1 wt % but at most about 2 wt % of diethylene glycol mono 2-ethylhexyl ether acrylate (EHDG-AT), at least about 45 wt % but at most about 65 wt % of butyl acrylate (BA), and at least about 5 wt % but at most about 15 wt % of perfluoroethyl acrylate (PFA), based on a total wt % of the first adhesive member. It will be understood that, in addition to such monomers, the first adhesive member 510 of Embodiment 1 may include an oligomer, a photoinitiator, and/or the like.

A surface inclination angle of the first adhesive member 510 according to Embodiment 1 may be at least about 15 degrees and at most about 20 degrees.

In Embodiment 2 of FIG. 6, the first adhesive member 510 may include at least about 1 wt % but at most about 2 wt % of hydroxy butyl acrylate (4-HBA), at least about 5 wt % but at most about 10 wt % of ethyl hexyl acrylate (2-EHA), at least about 1 wt % but at most about 2 wt % of diethylene glycol mono 2-ethylhexyl ether acrylate (EHDG-AT), at least about 30 wt % but at most about 40 wt % of butyl acrylate (BA), and at least about 15 wt % but at most about 25 wt % of perfluoroethyl acrylate (PFA), based on a total wt % of the first adhesive member. It will be understood that, in addition to such monomers, the first adhesive member 510 of Embodiment 2 may include an oligomer, a photoinitiator, and/or the like.

A surface inclination angle of the first adhesive member 510 according to Embodiment 2 may be at least about 20 degrees and at most about 30 degrees.

In Embodiment 3 of FIG. 6, the first adhesive member 510 may include at least about 1 wt % but at most about 2 wt % of hydroxy butyl acrylate (4-HBA), at least about 5 wt % but at most about 10 wt % of ethyl hexyl acrylate (2-EHA), at least about 1 wt % but at most about 2 wt % of diethylene glycol mono 2-ethylhexyl ether acrylate (EHDG-AT), at least about 20 wt % but at most about 30 wt % of butyl acrylate (BA), and at least about 25 wt % but at most about 35 wt % of perfluoroethyl acrylate (PFA), based on a total wt % of the first adhesive member. It will be understood that, in addition to such monomers, the first adhesive member 510 of Embodiment 3 may include an oligomer, a photoinitiator, and/or the like.

A surface inclination angle of the first adhesive member 510 according to Embodiment 3 may be at least about 30 degrees and at most about 40 degrees.

The first adhesive member 510 according to one or more embodiments may have the surface inclination angle θ1 that is at least about 15 degrees and at most about 40 degrees. This may be implemented by lowering the content (e.g., amount) of monomers with high surface energy and increasing the content (e.g., amount) of monomers with relatively low surface energy. More specifically, the surface energy of hydroxy butyl acrylate (4-HBA) may be 35 mN/m, the surface energy of ethylhexyl acrylate (2-EHA) may be 26 mN/m, the surface energy of tetrahydro furfuryl acrylate (THF-A) may be 38.3 mN/m, the surface energy of butyl acrylate (BA) may be 19.89mN/m, and the surface energy of perfluoroethyl acrylate (PFA) may be 15.43 mN/m. The content (e.g., amount) of hydroxy butyl acrylate (4-HBA), ethylhexyl acrylate (2-EHA), and tetrahydro furfuryl acrylate (THF-A) having high surface energy, for example, having surface energy greater than 20 mN/m, may be lowered and the content (e.g., amount) of butyl acrylate (BA) and perfluoroethyl acrylate (PFA) having relatively low surface energy, for example, having surface energy less than 20 mN/m, may be increased so that the first adhesive member 510 may have a relatively high surface inclination angle θ1. In one or more embodiments, as seen in the Embodiments 1 to 3 of FIG. 6, for example, a higher inclination angle may be obtained by relatively lowering the content (e.g., amount) of butyl acrylate (BA) and relatively increasing the content (e.g., amount) of perfluoroethyl acrylate (PFA).

Accordingly, in one or more embodiments, the width w1 of the inclined portion of the first adhesive member 510 may be about 1.19 times to about 3.73 times greater than a thickness t1 of the first adhesive member 510. More specifically, as the first adhesive member 510 is spread on the display panel 10, the first adhesive member 510 may have an inclined portion having a slope on the periphery of the display panel 10, for example, in the peripheral area PA. For example, the width w1 of the inclined portion of the first adhesive member 510 may correspond to a value obtained by multiplying the thickness t1 of the first adhesive member 510 by the cotangent of the surface inclination angle θ1 of the first adhesive member 510. If this is expressed in a formula, it may be expressed as w1=t1*cot(θ1).

Accordingly, if (e.g., when) the surface inclination angle θ1 of the first adhesive member 510 is at least about 15 degrees and at most about 40 degrees, the width w1 of the inclined portion of the first adhesive member 510 may be greater than about 1.19 times of the thickness t1 of the first adhesive member 510 but not more than about 3.73 times of the thickness t1 of the first adhesive member 510.

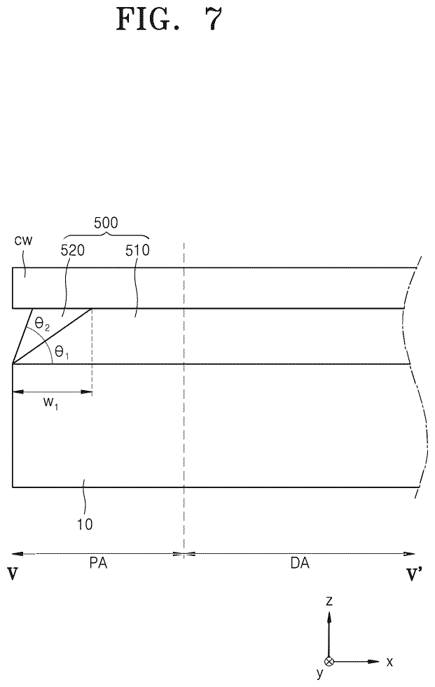

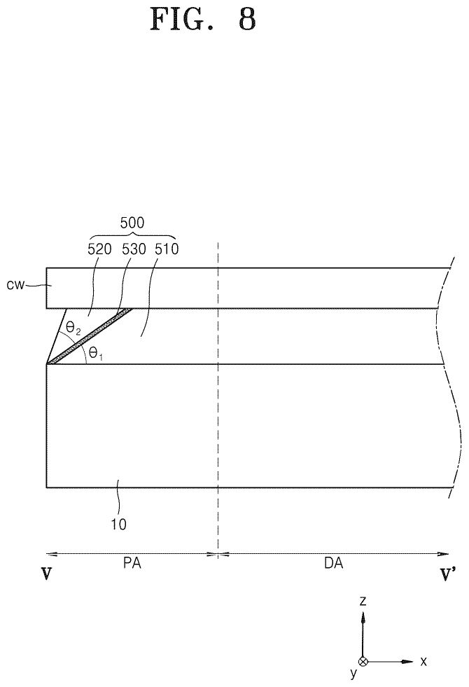

FIGS. 7 and 8 are schematic cross-sectional views of a display apparatus according to embodiments of the present disclosure and are similar to FIG. 5. The display apparatus according to the present embodiments is similar to the display apparatus described above, and thus, differences are mainly described.

Referring to FIG. 7, the adhesive member 500 may be arranged between the display panel 10 and the cover window CW. In one or more embodiments, the adhesive member 500 may include the first adhesive member 510 and a second adhesive member 520.

In one or more embodiments, the first adhesive member 510 may be an adhesive member as described in FIG. 5. For example, the first adhesive member 510 may be an adhesive member having components according to one of the Embodiments 1 to 3 described in more detail above.

The second adhesive member 520 may be arranged on the first adhesive member 510. The second adhesive member 520 may be an adhesive material capable of attaching the cover window CW to the display panel 10. In one or more embodiments, the second adhesive member 520 may be an optically clear resin (OCR).

The second adhesive member 520 may be arranged on the periphery of the first adhesive member 510. Accordingly, in the peripheral area PA, the second adhesive member 520 may be arranged on the first adhesive member 510 to overlap the first adhesive member 510. In one or more embodiments, the first adhesive member 520 may be supplementally arranged on an inclined portion of the first adhesive member 510. Because the second adhesive member 520 may be applied in a liquid state, the second adhesive member 520 may be inclined at a surface contact angle on the periphery of the first adhesive member 510. In one or more embodiments, after the second adhesive member 520 is applied to have the contact angle, the second adhesive member 520 may be hardened. Accordingly, the second adhesive member 520 may be inclined at a surface inclination angle θ2 to the first adhesive member 510 after being hardened. For example, a surface contact angle of the second adhesive member 520 in a liquid state to a lower layer of the second adhesive member 520 may turn into a surface inclination angle of the second adhesive member 520 as the second adhesive member 520 hardens. In other words, the surface contact angle of the second adhesive member 520 may have substantially the same value as the surface inclination angle of the second adhesive member 520. In this regard, the surface contact angle and the surface inclination angle of the second adhesive member 520 may be defined as an angle of inclination to a surface of a layer under the second adhesive member 520. For example, the surface contact angle and the surface inclination angle of the second adhesive member 520 may refer to an angle of inclination of the second adhesive member 520 to a surface of the first adhesive member 510.

By arranging the second adhesive member 520 as described above, a total inclination angle (θ1+θ2) of the adhesive member 500 may become larger, and a width of an inclined portion of the adhesive member 500 may become smaller. This may decrease a width of the peripheral area PA, thereby reducing dead space and maximizing or increasing the proportion of an area where an image is displayed in the display apparatus 1.

In one or more embodiments, the second adhesive member 520 may include the same material as the first adhesive member 510. For example, the first adhesive member 510 may be an adhesive member having components according to one of Embodiments 1 to 3 described above, and the second adhesive member 520 may also be an adhesive member having the same components and content (e.g., amount) as the first adhesive member 510. Accordingly, the surface inclination angle θ1 of the first adhesive member 510 may be at least about 15 degrees and at most about 40 degrees, and the surface inclination angle θ2 of the second adhesive member 520 may also be at least about 15 degrees but at most about 40 degrees. In one or more embodiments, the total inclination angle (θ1+θ2) of the adhesive member 500 may be at least about 30 degrees but at most about 80 degrees.

In one or more embodiments, the second adhesive member 520 may be different from the first adhesive member 510. For example, the content (e.g., amount) of components of the second adhesive member 520 may be different from the content (e.g., amount) of components of the first adhesive member 510. For example, the first adhesive member 510 may be an adhesive member having components according to one of Embodiments 1 to 3 described above, and the second adhesive member 520 may be an adhesive member having components according to another of Embodiments 1 to 3 described above. For example, the first adhesive member 510 may be an adhesive member having components according to Embodiment 1, and the second adhesive member 520 may be an adhesive member having components according to Embodiment 2. In one or more embodiments, the first adhesive member 510 may be an adhesive member having components according to Embodiment 2, and the second adhesive member 520 may be an adhesive member having components according to Embodiment 1.

In one or more embodiments, the first adhesive member 510 may be a general adhesive member having components according to the above comparative example, and the second adhesive member 520 may be an adhesive member having components according to one of Embodiments 1 to 3 described above.

In one or more embodiments, the surface inclination angle θ2 of the second adhesive member 520 may be greater than the surface inclination angle θ1 of the first adhesive member 510. For example, the surface inclination angle θ1 of the first adhesive member 510 may be at least about 15 degrees but at most about 20 degrees, and the surface inclination angle θ2 of the second adhesive member 520 may be at least about 20 degrees but at most about 30 degrees. To this end, it will be understood that, for example, the first adhesive member 510 may be an adhesive member having components according to Embodiment 1 and the second adhesive member 520 may be an adhesive member having components according to Embodiment 2. In one or more embodiments, the content (e.g., amount) of butyl acrylate (BA) in the second adhesive member 520 may be less than the content (e.g., amount) of butyl acrylate (BA) in the first adhesive member 510. In one or more embodiments, the content (e.g., amount) of perfluoroethyl acrylate (PFA) in the second adhesive member 520 may be greater than the content (e.g., amount) of perfluoroethyl acrylate (PFA) in the first adhesive member 510.

Referring to FIG. 8, the adhesive member 500 may further include a coating layer 530 arranged between the first adhesive member 510 and the second adhesive member 520. More specifically, the coating layer 530 may be arranged on the periphery, for example, the inclined portion, of the first adhesive member 510. Accordingly, the coating layer 530 may overlap the first adhesive member 510 and the second adhesive member 520 in the peripheral area PA. In one or more embodiments, because the coating layer 530 is arranged on the inclined portion of the first adhesive member 510, the coating layer 530 may be inclined with respect to the display panel 10.

In one or more embodiments, the coating layer 530 may include a hydrophobic material. For example, the coating layer 530 may include at least one of polysiloxane, fluoro alkylsilane, nanocomposite fluoropolymer, trifluoromethyl methacrylate, and/or trimethylsilyl methacrylate. As the coating layer 530 includes a hydrophobic material, the surface inclination angle θ2 of the second adhesive member 520 spread on the coating layer 530 may be increased.

In one or more embodiments, the first adhesive member 510 and the second adhesive member 520 may be adhesive members having components according to the above comparative example. In one or more embodiments, similar to that described above, the first adhesive member 510 and the second adhesive member 520 may include different materials from each other, and for example, the first adhesive member 510 may be an adhesive member having components according to the comparative example and the second adhesive member 520 may be an adhesive member having components according to one of Embodiments 1 to 3 described above. In one or more embodiments, the first adhesive member 510 may be an adhesive member having components according to one of Embodiments 1 to 3 described above, and the second adhesive member 520 may be an adhesive member having components according to another of Embodiments 1 to 3 described above.

The components may be configured such that the surface inclination angle θ2 of the second adhesive member 520 is greater than the surface inclination angle θ1 of the first adhesive member 510. For example, the content (e.g., amount) of butyl acrylate (BA) in the second adhesive member 520 may be less than the content (e.g., amount) of butyl acrylate (BA) in the first adhesive member 510. In one or more embodiments, the content (e.g., amount) of perfluoroethyl acrylate (PFA) in the second adhesive member 520 may be greater than the content (e.g., amount) of perfluoroethyl acrylate (PFA) in the first adhesive member 510.

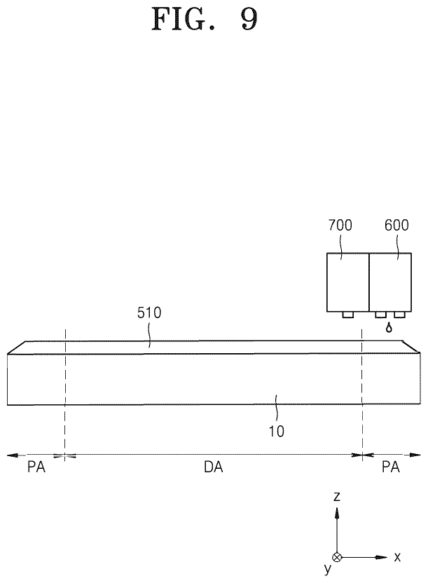

FIGS. 9 to 14 are schematic diagrams of a method of manufacturing a display apparatus, according to one or more embodiments of the present disclosure. The method of manufacturing a display apparatus according to FIGS. 9 to 14 may be a method for manufacturing the display apparatus 1 described above. However, the present disclosure is not limited thereto.

Referring to FIG. 9, from above the display panel 10, a spray portion 600 may discharge a liquid droplet to the display panel 10 in one direction. For example, the spray portion 600 may coat the display area DA and the peripheral area PA of the display panel 10 with the first adhesive member 510 in a droplet state. The first adhesive member 510 is in a droplet state, and thus, as shown in FIG. 9, may have a slope on the periphery of the display panel 10, for example, in the peripheral area PA.

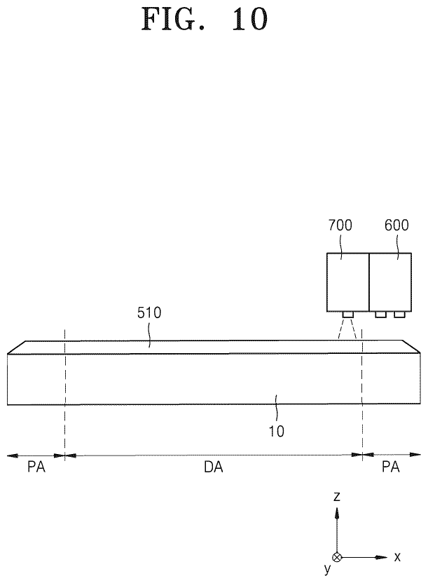

Next, referring to FIG. 10, the first adhesive member 510 in a droplet state may be hardened by a hardening portion 700 adjacent to the spray portion 600. In one or more embodiments, the hardening portion 700 may harden the liquid droplet by radiating light through a light-emitting member. The light-emitting member may include a LED module. The light-emitting member may radiate ultraviolet rays or infrared rays. A wavelength of light radiated by the light-emitting member may be selected depending on the type or kind of liquid droplet or the type or kind of photoinitiator. Hereinafter, a case where the light-emitting member hardens the liquid droplet by radiating ultraviolet rays will be mainly described for convenience and the present disclosure is not limited thereto.

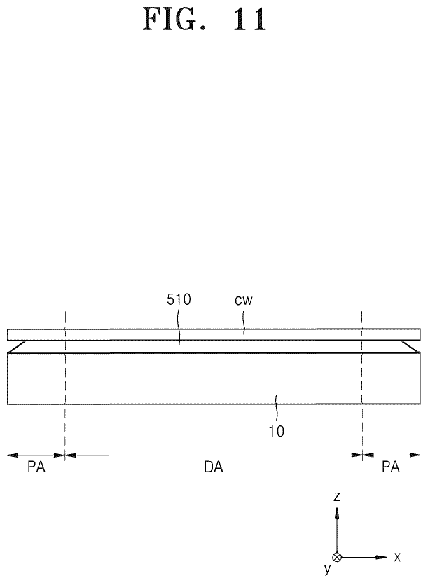

Referring to FIG. 11, the cover window CW may be attached to the display panel 10. In this regard, the cover window CW may be attached to the display panel 10 by the first adhesive member 510, and the first adhesive member 510 may be an adhesive member having components according to the first to third embodiments described above. Accordingly, because a surface inclination angle of the first adhesive member 510 is large, dead space may be reduced.

In one or more embodiments, after the cover window CW is attached to the display panel 10, the first adhesive member 510 may be hardened once again.

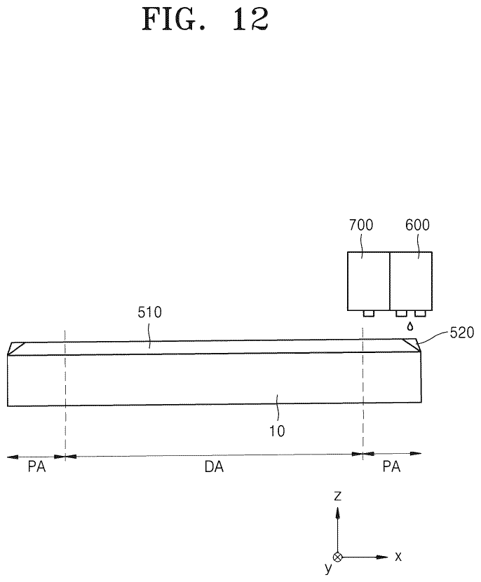

Referring to FIG. 12, before the cover window CW is attached to the display panel 10, the second adhesive member 520 may be spread on the periphery of the first adhesive member 510 by the spray portion 600 again. The second adhesive member 520 has been described above, and thus, a redundant description thereof may not be provided. The second adhesive member 520 in a droplet state may be applied and then hardened by the hardening portion 700.

In one or more embodiments, it will be understood that the cover window CW may be attached to the display panel 10 after the second adhesive member 520 is hardened. In one or more embodiments, after the cover window CW is attached to the display panel 10, the first adhesive member 510 and the second adhesive member 520 may be hardened once again.

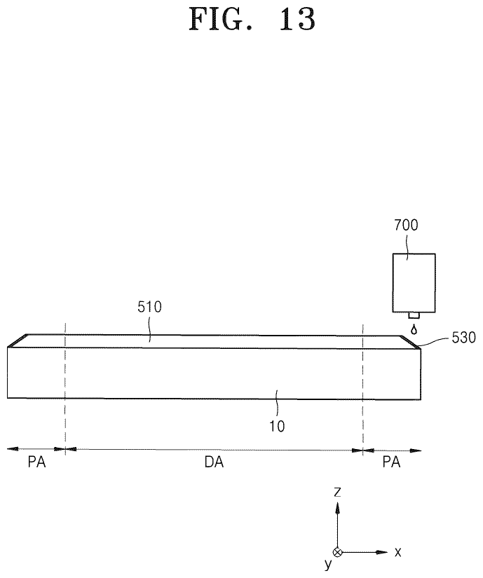

Referring to FIG. 13, after the first adhesive member 510 is applied and hardened, the coating layer 530 may be formed. In one or more embodiments, the coating layer 530 is a hydrophobic coating, and in a liquid state where a hydrophobic material is mixed with a solvent, may be applied to the first adhesive member 510. In this regard, a liquid hydrophobic material may be spread on the periphery of the first adhesive member 510, for example, mainly on an inclined portion of the first adhesive member 510. In one or more embodiments, the liquid hydrophobic material may be applied by a sprayer or a dispenser. As the applied liquid hydrophobic material hardens, the solvent may be evaporated and removed, and only the hydrophobic material may remain on the first adhesive member 510 to form (or provide) the coating layer 530.

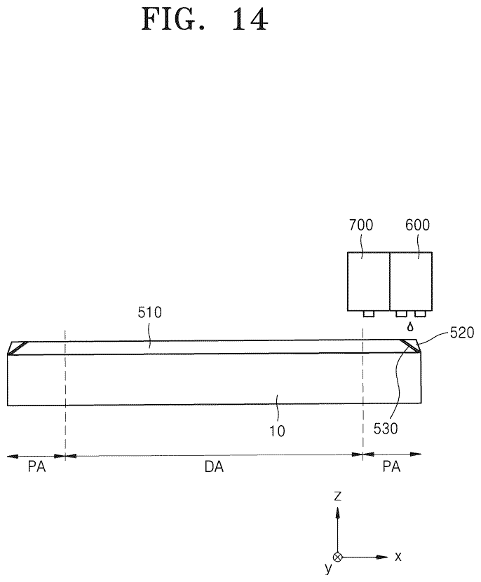

Next, referring to FIG. 14, similar to that shown in FIG. 12, the second adhesive member 520 may be spread on the coating layer 530 and hardened. In one or more embodiments, it will be understood that the cover window CW may be attached to the display panel 10 after the second adhesive member 520 is hardened. In one or more embodiments, after the cover window CW is attached to the display panel 10, the first adhesive member 510, the second adhesive member 520, and the coating layer 530 may be hardened once again.

According to aspects of one or more of the embodiments described above, a display apparatus having a steep edge through an adhesive member having an improved inclination angle may be implemented.

Accordingly, the width of a peripheral area may be reduced, and the area of a dead space may be reduced.

Effects of one or more embodiments are not limited thereto, and other unmentioned effects will be apparent to one of ordinary skill in the art from the following claims and equivalents thereof.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ±30%, 20%, 10%, 5% of the stated value.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Further, the use of “may” when describing embodiments of the present disclosure refers to “one or more embodiments of the present disclosure.”

The light emitting device, electronic apparatus or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

It should be understood that embodiments described herein should be considered in a descriptive sense only and not for purposes of limitation. Descriptions of features or aspects within each embodiment should typically be considered as available for other similar features or aspects in other embodiments. Although the embodiments of the present disclosure have been described, it is understood that the present disclosure should not be limited to these embodiments, but one or more suitable changes and modifications can be made by one ordinary skilled in the art within the spirit and scope of the present disclosure as defined by the following claims and equivalents thereof.

What is claimed is:

1. A display apparatus comprising:
a display panel;
a cover window covering one surface of the display panel; and
a first adhesive member between the display panel and the cover window,
wherein a surface inclination angle of the first adhesive member is at least about 15 degrees and at most about 40 degrees.

2. The display apparatus of claim 1, wherein the first adhesive member comprises a hydrophobic material.

3. The display apparatus of claim 2, wherein the first adhesive member comprises at least one of butyl acrylate or perfluoroethyl acrylate.

4. The display apparatus of claim 3, wherein the first adhesive member comprises butyl acrylate and an amount of the butyl acrylate is about 20 wt % to about 65 wt % based on a total wt % of the first adhesive member.

5. The display apparatus of claim 3, wherein the first adhesive member comprises perfluoroethyl acrylate and an amount of the perfluoroethyl acrylate is about 5 wt % to about 35 wt % based on a total wt % of the first adhesive member.

6. The display apparatus of claim 1, wherein the first adhesive member is in a display area and a peripheral area of the display panel, the peripheral area being around the display area.

7. The display apparatus of claim 6, wherein the first adhesive member comprises an inclined portion inclined with respect to the display panel in the peripheral area, and a width of the inclined portion of the first adhesive member is about 1.19 times to about 3.73 times greater than a thickness of the first adhesive member.

8. The display apparatus of claim 1, further comprising a second adhesive member on a periphery of the first adhesive member.

9. The display apparatus of claim 8, wherein the second adhesive member comprises the same material as a material of the first adhesive member.

10. The display apparatus of claim 8, wherein the second adhesive member comprises a different material from the first adhesive member.

11. The display apparatus of claim 10, wherein a surface inclination angle of the second adhesive member is greater than the surface inclination angle of the first adhesive member.

12. The display apparatus of claim 10, wherein the first adhesive member and the second adhesive member each comprise butyl acrylate,
wherein an amount of the butyl acrylate in the second adhesive member is less than an amount of the butyl acrylate in the first adhesive member.

13. The display apparatus of claim 10, wherein the first adhesive member and the second adhesive member each comprise perfluoroethyl acrylate,
wherein an amount of the perfluoroethyl acrylate in the second adhesive member is greater than an amount of the perfluoroethyl acrylate in the first adhesive member.

14. The display apparatus of claim 8, further comprising a hydrophobic coating layer between the first adhesive member and the second adhesive member.

15. A method of manufacturing a display apparatus, the method comprising:
preparing a display panel;
arranging a first adhesive member in a display area and a peripheral area of the display panel; and
attaching, by arranging a cover window on the first adhesive member, the cover window to the display panel,
wherein a surface inclination angle of the first adhesive member is at least about 15 degrees and at most about 40 degrees.

16. The method of claim 15, wherein the first adhesive member comprises at least one of butyl acrylate or perfluoroethyl acrylate.

17. The method of claim 16, wherein the first adhesive member comprises butyl acrylate and an amount of the butyl acrylate is about 20 wt % to about 65 wt %.

18. The method of claim 16, wherein the first adhesive member comprises perfluoroethyl acrylate and an amount of the perfluoroethyl acrylate is about 5 wt % to about 35 wt %.

19. The method of claim 15, further comprising arranging a second adhesive member on a periphery of the first adhesive member.

20. The method of claim 19, further comprising coating a hydrophobic material between the first adhesive member and the second adhesive member.
